(19) United States
(12) Patent Application Publication
(10) Pub. No.: US 2014/0008614 A1
(43) Pub. Date: Jan. 9, 2014

(54) PHOTODIODE AND METHOD FOR PRODUCING THE SAME

(71) Applicants: Kei Fujii, Itami-shi (JP); Takashi Ishizuka, Itami-shi (JP); Katsushi Akita, Itami-shi (JP)

(72) Inventors: Kei Fujii, Itami-shi (JP); Takashi Ishizuka, Itami-shi (JP); Katsushi Akita, Itami-shi (JP)

(73) Assignee: Sumitomo Electric Industries, Ltd., Osaka-shi (JP)

(21) Appl. No.: 14/007,435

(22) PCT Filed: Apr. 4, 2012
(86) PCT No.: PCT/JP2012/059137

§ 371 Date: Sep. 25, 2013

(30) Foreign Application Priority Data
Apr. 8, 2011 (JP) 2011-086615

(51) Int. Cl. H01L 31/0352

(52) U.S. Cl. CPC H01L 31/035236
USPC 257/21; 438/87

(57) ABSTRACT

Provided is, for example, a photodiode in which extension of the sensitivity range to a longer wavelength in the near-infrared region can be achieved without increasing the dark current. A photodiode according to the present invention includes an absorption layer 3 that is positioned on an InP substrate 1 and has a type-II multiple-quantum well structure in which an InGaAs layer 3a and a GaAsSb layer 3b are alternately layered, wherein the InGaAs layer or the GaAsSb layer has a composition gradient in the thickness direction in which the bandgap energy of the InGaAs or the GaAsSb decreases toward the top surface or the bottom surface of the layer.

### TECHNICAL FIELD

The present invention relates to a photodiode and a method for producing the photodiode. Specifically, the present invention relates to a photodiode including a type-II multiple-quantum well structure (hereafter, referred to as MQW) having sensitivity in the near-infrared region in which extension of the sensitivity range to a longer wavelength can be achieved without increasing the dark current; and a method for producing the photodiode.

### BACKGROUND ART

InP-based semiconductors, which are III-V compound semiconductors, have a bandgap energy corresponding to the near-infrared region and hence a large number of studies are performed for developing photodiodes for communications, image capturing at night, and the like.

For example, Non Patent Literature 1 proposes a photodiode in which an InGaAs/GaAsSb type-II MQW is formed on an InP substrate and a p-n junction is formed with a p-type or n-type epitaxial layer to achieve a cutoff wavelength of 2.39 μm, the photodiode having characteristic sensitivity in a wavelength range of 1.7 μm to 2.7 μm.

In addition, Non Patent Literature 2 describes a photodiode having a type-II MQW absorption layer having 150 pairs layered such that 5 nm InGaAs and 5 nm GaAsSb constitute a single pair, the photodiode having characteristic sensitivity (200 K, 250 K, and 295 K) in a wavelength range of 1 μm to 3 μm.

### CITATION LIST

### Non Patent Literature

NPL 1: R. Sidhu, et. al. “A Long-Wavelength Photodiode on InP Using Lattice-Matched GaInAs—GaAsSb Type-II Quantum Wells”, IEEE Photonics Technology Letters, Vol. 17, No. 12 (2005), pp. 2715-2717
NPL 2: R. Sidhu, et. al. “A 2.3 μm Cutoff Wavelength Photodiode on InP Using Lattice-Matched GaInAs—GaAsSb Type-II Quantum Wells”, 2005 International Conference on Indium Phosphide and Related Materials, pp. 148-151

### SUMMARY OF INVENTION

### Technical Problem

In order to widen the application fields of the above-described photodiodes constituted by semiconductor elements, the sensitivity range is desirably extended to as long a wavelength as possible. However, regardless of type I or type II, the smaller the bandgap energy, the higher the dark current tends to become. In particular, the following analytic solution has been obtained: the smaller the bandgap energy, the higher the diffusion current and the generation-recombination current, which are main components of the dark current. Accordingly, while the dark current is addressed by improvements in factors other than the bandgap energy, extension of the sensitivity range to a longer wavelength has been pursued by decreasing the bandgap energy.

An object of the present invention is to provide a photodiode in which extension of the sensitivity range to a longer wavelength in the near-infrared region can be achieved without increasing the dark current; and a method for producing the photodiode.

### Solution to Problem

A photodiode according to the present invention contains a III-V compound semiconductor. This photodiode includes an absorption layer that is positioned on a III-V compound semiconductor substrate and has a type-II multiple-quantum well structure in which a first semiconductor layer and a second semiconductor layer are alternately layered, wherein the first semiconductor layer has a composition gradient in a thickness direction in which a bandgap energy of the first semiconductor layer decreases toward a top surface or a bottom surface of the first semiconductor layer.

In the above-described configuration, the layer has a composition gradient in which the bandgap energy decreases toward an end surface (top surface or bottom surface) of the layer and the bandgap energy is minimized at the end surface. That is, the valence band is at the highest energy level and the conduction band is at the lowest energy level. Accordingly, regardless of whether the first semiconductor layer in a type-II multiple-quantum well structure is the layer having a higher valence band or the layer having a lower valence band, the bandgap energy of type-II transition (energy difference of type-II transition) is small.

Specifically, (1) when the first semiconductor layer is the layer having a higher valence band, upon receiving of light, an electron in the valence band of the first semiconductor layer undergoes type-II transition to the conduction band of the second semiconductor layer. In this case, the valence band of the first semiconductor layer is at a high energy level due to the above-described composition gradient, and hence the energy difference of the type-II transition is small. As a result, extension of the sensitivity range to a longer wavelength is achieved.

Alternatively, (2) when the first semiconductor layer is the layer having a lower valence band, upon receiving of light, an electron in the valence band of the second semiconductor layer undergoes type-II transition to the conduction band of the first semiconductor layer. In this case, the conduction band of the first semiconductor layer is at a low energy level due to the above-described composition gradient, and hence the energy difference of the type-II transition is small. As a result, extension of the sensitivity range to a longer wavelength is achieved.

In summary, regardless of whether the first semiconductor layer is the layer having a higher valence band or the layer having a lower valence band, the energy difference of type-II transition is small and extension of the sensitivity range to a longer wavelength is achieved.

The dark current will be described below. In the first semiconductor layer, the bandgap energy is maximized at an end surface that is on the side opposite to the end surface at which the bandgap energy is minimized. A bandgap energy corresponding to the average composition of the first semiconductor layer is the average bandgap energy of the first semiconductor layer. The dark current depends on this average bandgap energy. Accordingly, for example, while the dark current is kept at a constant level based on the average composition of the first semiconductor layer, the bandgap energy can be minimized at an end surface of the first semiconductor layer to thereby achieve the extension to a longer wavelength.

Note that, in the first semiconductor layer and the second semiconductor layer, first and second do not denote the layering order or the like. For example, the “first” may be replaced by “one” and the “second” may be replaced by “another”. The first semiconductor layer in the band structure of a type-II multiple-quantum well structure may be the layer having a higher valence band or the layer having a lower valence band.

The second semiconductor layer may have a composition gradient in a thickness direction in which a bandgap energy of the second semiconductor layer decreases toward a surface of the second semiconductor layer, the surface being in contact with an end surface of the first semiconductor layer having the gradient in which the bandgap energy of the first semiconductor layer decreases toward the end surface.

In the above-described configuration, a surface of the second semiconductor layer toward which the bandgap energy decreases and at which the bandgap energy is minimized can be made to be in contact with a surface of the first semiconductor layer at which the bandgap energy is minimized. This contact between surfaces at which the bandgap energy is minimized provides the following band structure at this interface. That is, the valence band of the layer having a higher valence band is at a high energy level while the conduction band of the layer having a lower valence band is at a low energy level. As a result, upon receiving of light causing type-II transition, an electron in the valence band of the layer having a higher valence band undergoes transition to the conduction band of the layer having a lower valence band. Thus, the energy difference is decreased to its lower limit and this interface is referred to as an interface at a lower limit of effective bandgap energy.

In the first and second semiconductor layers, at surfaces on the side opposite to the interface at the lower limit, the bandgap energies of the layers are maximized due to the composition gradients and this interface is referred to as an interface at an upper limit of effective bandgap energy. The interface at a lower limit of effective bandgap energy and the interface at an upper limit of effective bandgap energy are alternately disposed in the thickness direction.

In at least one semiconductor layer that is selected from the first semiconductor layer and the second semiconductor layer and has the composition gradient, a composition at an end surface at which the bandgap energy is minimized preferably corresponds to a lattice mismatch of more than 0.2% in terms of variation in lattice constant with respect to an average composition of the semiconductor layer.

In this case, while extension of the sensitivity range of the photodiode to a longer wavelength is achieved, the dark current can be suppressed to a low value.

In at least one semiconductor layer selected from the first semiconductor layer and the second semiconductor layer, an average composition preferably corresponds to a lattice mismatch within ±1% in terms of variation in lattice constant with respect to the III-V compound semiconductor substrate.

In this case, the average lattice mismatch of such a semiconductor layer with respect to the III-V compound semiconductor substrate can be limited within the predetermined range. Thus, while the composition gradient is provided in the thickness direction, generation of misfit dislocations can be suppressed.

One of the first and second semiconductor layers that has a higher valence band in terms of potential energy than another one of the first and second semiconductor layers preferably contains at least one of Ga, As, and Sb.

In this case, in a type-II multiple-quantum well structure, the semiconductor layer having a higher valence band can be formed of a III-V compound semiconductor such as GaAsSb.

One of the first and second semiconductor layers that has a lower valence band in terms of potential energy than another one of the first and second semiconductor layers preferably contains at least one of In, Ga, and As.

In this case, in a type-II multiple-quantum well structure, the semiconductor layer having a lower valence band can be formed of a III-V compound semiconductor such as InGaAs.

The multiple-quantum well structure is preferably formed such that an InₓGa₁₋ₓAs layer has an average composition xₐᵥₑ (0.38≦xₐᵥₑ≦0.68) and a GaAs_{1-y}Sb_{y} layer has an average composition yₐᵥₑ (0.36≦yₐᵥₑ≦0.62).

In this case, in the formation of a type-II multiple-quantum well structure, the average lattice mismatch of each of the InGaAs layer and the GaAsSb layer with respect to the substrate can be limited within a predetermined range. Thus, the above-described composition gradients can be easily provided in the thickness direction without introduction of misfit dislocations.

Note that “an InₓGa₁₋ₓAs layer has an average composition xₐᵥₑ (0.38≦xₐᵥₑ≦0.68)” means the following: In a compound semiconductor layer represented by a chemical formula InₓGa₁₋ₓAs, x in the formula indicates that there is a gradient in the thickness direction of the compound semiconductor layer; there is naturally the average value xₐᵥₑ in the thickness direction and the range of the average value xₐᵥₑ is 0.38≦xₐᵥₑ≦0.68. Similarly, yₐᵥₑ in the GaAs_{1-y}Sb_{y} layer is understood.

When each of the average composition range of the InₓGa₁₋ₓAs layer and the average composition range of the GaAs_{1-y}Sb_{y} layer is employed from one end to the other end of the whole range, there are cases where a ternary compound semiconductor is not formed at the above-described end surface. In such a case, for example, even in the case where GaAsSb is not formed but GaSb is formed at the end surface and a GaSb layer is deposited at the end surface, when this layer has a thickness of about a single atom, the semiconductor layer can be grown without introduction of misfit dislocations. In addition, the dark current is not increased. Accordingly, semiconductor crystals at the above-described end surfaces should be construed in a broad and flexible sense.

The III-V compound semiconductor substrate is preferably an InP substrate.

In this case, efficient mass production of photodiodes can be achieved with large-diameter InP substrates, which are easily available.

A method for producing a photodiode according to the present invention provides a photodiode containing a III-V compound semiconductor. This production method includes a step of forming an absorption layer having a type-II multiple-quantum well structure by alternately layering a first semiconductor layer and a second semiconductor layer on an InP substrate, wherein, in the step of forming the multiple-quantum well structure, the first semiconductor layer is formed so as to have a composition gradient in a thickness direction in which a bandgap energy of the first semiconductor layer decreases toward a top surface or a bottom surface of the first semiconductor layer.

By using this method, extension of the absorption range to a longer wavelength can be achieved without changing (increasing) the dark current.

In the step of forming the multiple-quantum well structure, the second semiconductor layer is preferably formed so as to have a composition gradient in a thickness direction in which a bandgap energy of the second semiconductor layer decreases toward a surface of the second semiconductor layer, the surface being in contact with an end surface of the first semiconductor layer having the gradient in which the bandgap energy of the first semiconductor layer decreases toward the end surface.

In this case, the interface at a lower limit of effective bandgap energy can be easily formed to further decrease the energy difference of type-II transition. In this case, naturally, the interface at an upper limit of effective bandgap energy is also formed alternately. Accordingly, the average compositions are not changed and the average bandgap energy is also not changed. Therefore, a low dark current can be maintained.

When the multiple-quantum well structure is formed by metal-organic vapor phase epitaxy using only metal-organic sources such that the first semiconductor layer or each of the first semiconductor layer and the second semiconductor layer is formed so as to have the composition gradient, the composition gradient is preferably provided by adjusting a mass-flow controller (MFC) incorporated in a growth system for the metal-organic vapor phase epitaxy using only metal-organic sources. Here, the metal-organic vapor phase epitaxy using only metal-organic sources denotes epitaxy in which only metal-organic sources composed of metal-organic compounds are used as the sources for the vapor phase epitaxy, and is referred to as all metal-organic source MOVPE.

By using metal-organic vapor phase epitaxy using only metal-organic sources, the growth temperature can be decreased and an epitaxial layered body having high quality can be obtained. During the metal-organic vapor phase epitaxy using only metal-organic sources, the supply rates of components of the first and second semiconductor layers are controlled with mass-flow controllers to achieve intended variations in the compositions. The control of supply rates with mass-flow controllers can be precisely achieved with high accuracy. Accordingly, the above-described gradients can be stably provided with high reproducibility.

### Advantageous Effects of Invention

In a photodiode or the like according to the present invention, extension of the sensitivity range to a longer wavelength in the near-infrared region can be achieved while a low dark current is maintained.

### BRIEF DESCRIPTION OF DRAWINGS

FIG. 1 illustrates a photodiode according to an embodiment of the present invention. An absorption layer 3 has a multiple-quantum well structure formed by layering 50 to 300 quantum wells of InGaAs 3a/GaAsSb 3b. At interfaces 16 and 17 of a photodiode 10, oxygen and carbon concentrations are each less than 1×10¹⁷ cm⁻³.

FIG. 2 is an explanatory view of composition gradients (slopes) of an InₓGa₁₋ₓAs layer and a GaAs_{1-y}Sb_{y} layer constituting an MQW. The left half of FIG. 2 illustrates the semiconductor layers. The right half of FIG. 2 illustrates distributions of compositions in the semiconductor layers.

FIG. 3 illustrates a band structure in the case where both InGaAs and GaAsSb have composition gradients.

FIG. 4 illustrates a band structure in the case where GaAsSb alone has a composition gradient and InGaAs has a flat composition.

FIG. 5 illustrates the piping system and the like of a deposition apparatus employing all metal-organic source MOVPE.

FIG. 6 is a flow chart of a method for producing a photodiode according to the present invention.

### REFERENCE SIGNS LIST

InP substrate; 2 buffer layer (InP and/or InGaAs); 3 type-II MQW absorption layer; 3a InGaAs layer; 3b GaAsSb layer; 4 InGaAs layer (diffusive-concentration-distribution-adjusting layer); 5 InP window layer; 6 p-type region; 10 photodiode; 11 p-electrode (pixel electrode); 12 ground electrode (n-electrode); 16 interface between MQW and InGaAs layer; 17 interface between InGaAs layer and InP window layer; 35 antireflection (AR) film; 36 selective diffusion mask pattern; 50a wafer (intermediate product); 60 deposition apparatus employing metal-organic vapor phase epitaxy using only metal-organic sources; 61 infrared thermometer; 63 reaction chamber; 65 quartz tube; 69 window of reaction chamber; 66 substrate table; 66h heater; K interface at lower limit of (minimum) effective bandgap energy; L interface at upper limit of (maximum) effective bandgap energy.

### DESCRIPTION OF EMBODIMENTS

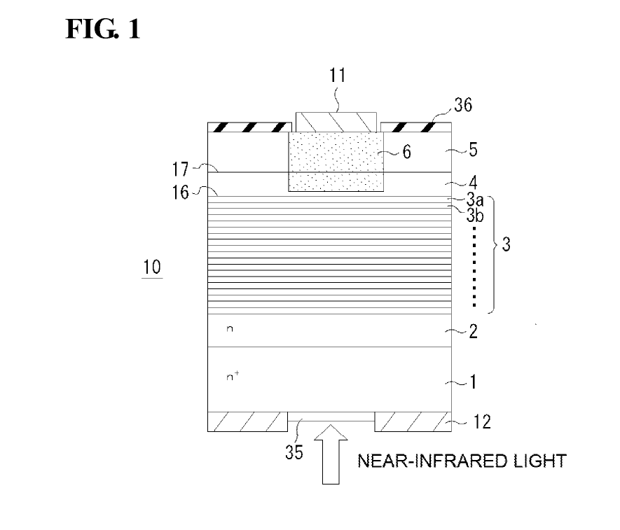

FIG. 1 illustrates a photodiode 10 according to an embodiment of the present invention. The photodiode 10 has, on an InP substrate 1, an InP-based semiconductor layered structure (epitaxial wafer) having a configuration described below. In FIG. 1, light is received on the InP substrate side. Alternatively, light may be received on the epitaxial side. Note that a multiple-quantum well structure is abbreviated as MQW. (InP substrate 1/InP or InGaAs buffer layer 2/absorption layer 3 having type-II (InGaAs/GaAsSb) MQW/InGaAs diffusive-concentration-distribution-adjusting layer 4/InP window layer 5)

A p-type region 6 extends from the InP window layer 5 in the depth direction. This p-type region 6 is formed by selective diffusion of Zn, which is a p-type impurity, through the openings of a SiN film serving as a selective diffusion mask pattern 36. This diffusion introduction into a region delimited in plan inside the periphery of the photodiode 10 is achieved by selective diffusion through the SiN film serving as the selective diffusion mask pattern 36. A p-electrode 11 formed of AuZn is disposed so as to be in ohmic contact with the p-type region 6; and an n-electrode 12 formed of AuGeNi is disposed so as to be in ohmic contact with the rear surface of the InP substrate 1. In this case, the InP substrate 1 is doped with an n-type impurity to ensure a predetermined level of conductivity. On the rear surface of the InP substrate 1, an antireflection film 35 formed of SiON is formed to provide a structure for receiving light incident on the rear surface of the InP substrate. In the absorption layer 3 having the type-II MQW, a p-n junction is formed at the boundary front of the p-type region 6. By applying a reverse bias voltage between the p-electrode 11 and the n-electrode 12, a depletion layer is formed in a larger area on a side in which the concentration of the n-type impurity is lower (n-type impurity background concentration). The background impurity concentration in the absorption layer 3 having an MQW is, in terms of n-type impurity concentration (carrier concentration), about 5×10¹⁵ cm⁻³ or less. The position of the p-n junction is determined from the point of intersection of the background impurity concentration (n-type carrier concentration) and the concentration profile of p-type impurity Zn in the absorption layer 3 having a multiple-quantum well. The diffusive-concentration-distribution-adjusting layer 4 is formed to adjust the concentration distribution of the p-type impurity in the MQW constituting the absorption layer 3. Alternatively, the diffusive-concentration-distribution-adjusting layer 4 may be omitted. In the absorption layer 3, the Zn concentration is preferably 5×10¹⁶ cm⁻³ or less.

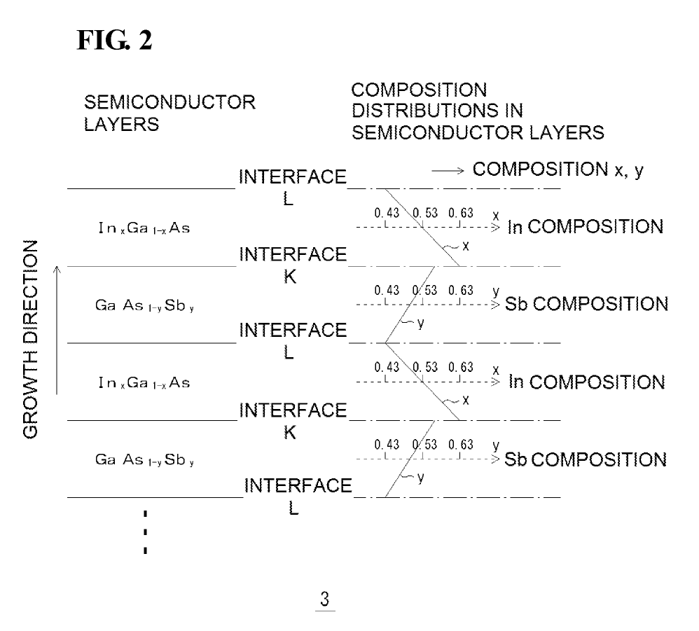

FIG. 2 is an explanatory view of composition gradients (slopes) of an InₓGa₁₋ₓAs layer 3a and a GaAs_{1-y}Sb_{y} layer 3b constituting the type-II MQW in the absorption layer 3. The left half of FIG. 2 illustrates the semiconductor layers 3a and 3b. The right half of FIG. 2 illustrates distributions of compositions x and y in the semiconductor layers 3a and 3b. As illustrated in FIG. 2, the composition x of the InₓGa₁₋ₓAs layer 3a at the center of the thickness is 0.53. The average composition xₐᵥₑ is 0.53, which allows lattice match to InP. Toward an interface K, the composition x increases to about 0.63. On the opposite side of the InₓGa₁₋ₓAs layer 3a, that is, toward an interface L, the composition x decreases to about 0.43. In summary, in the InₓGa₁₋ₓAs layer 3a, the composition x increases from about 0.43 at the interface L to about 0.63 at the interface K.

On the other hand, the composition y of the GaAs_{1-y}Sb_{y} layer 3b at the center of the thickness is about 0.49. The average composition yₐᵥₑ is 0.49, which allows lattice match to InP. Toward the interface K, the composition y increases to about 0.54. In the GaAs_{1-y}Sb_{y} layer 3b, the composition y increases from 0.43 at the interface L to about 0.54 at the interface K.

In FIG. 2, each of the compositions x and y linearly changes in the thickness direction and the composition at the center of the thickness is equal to the average composition. However, it is not necessary for the composition gradients to be linear. The composition may increase in a stepped form or a wavy or rippled form as long as the composition macroscopically has a gradient. Accordingly, the composition at the center of the thickness is not necessarily equal to the average composition.

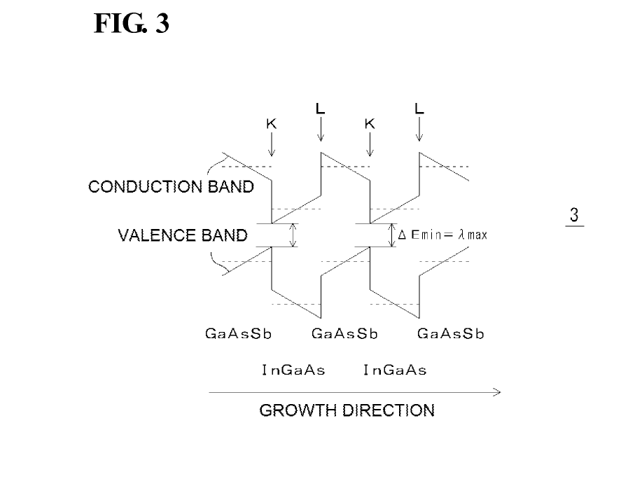

FIG. 3 illustrates the band structure of an MQW having the gradients of compositions x and y illustrated in FIG. 2. In the InₓGa₁₋ₓAs layer 3a, the In composition x decreases in the growth direction (in the thickness direction toward the top surface). On the other hand, in the GaAs_{1-y}Sb_{y} layer 3b, the Sb composition y increases in the growth direction. These composition gradients result in the formation of the interfaces K and L as illustrated in FIGS. 2 and 3. At the interface K, both of the composition x of the InₓGa₁₋ₓAs layer 3a and the composition y of the GaAs_{1-y}Sb_{y} layer 3b have maximum values. Because of these composition changes, as illustrated in FIG. 3, the bandgap energies of the semiconductor layers decrease toward the interface K between the semiconductor layers. In type-II transition, an electron in the valence band of the GaAs_{1-y}Sb_{y} layer 3b, which has the higher valence band, absorbs optical energy and undergoes transition to the conduction band of the InₓGa₁₋ₓAs layer 3a. As a result of this type-II transition, a hole is generated in the valence band of the GaAs_{1-y}Sb_{y} layer 3b and an electron is generated in the conduction band of the InₓGa₁₋ₓAs layer 3a so as to constitute a pair (generation of an electron-hole pair). The energy difference between the valence band of the GaAs_{1-y}Sb_{y} layer 3b and the conduction band of the InₓGa₁₋ₓAs layer 3a at the interface K is the minimum energy ΔEmin, which corresponds to a light wavelength that is the long-wavelength limit λmax. The interface K can be referred to as an interface at a lower limit of effective bandgap energy. In contrast, the interface L can be referred to as an interface at an upper limit of effective bandgap energy.

Points in the above-described embodiment of the present invention are summarized as follows.

### 1. Extension to Longer Wavelength:

In the above-described MQW, a semiconductor layer having a composition gradient in which the bandgap energy decreases has a minimum bandgap energy at an end surface (top surface or bottom surface) of the layer. Specifically, at the end surface, the valence band is at its highest energy level and the conduction band is at its lowest energy level in the semiconductor layer. Accordingly, at the interface K at which end surfaces of the InₓGa₁₋ₓAs layer 3a and the GaAs_{1-y}Sb_{y} layer 3b having small bandgap energies are in contact with each other, the valence band and the conduction band are closest to each other. The valence band of the GaAs_{1-y}Sb_{y} layer 3b is at a higher energy level than the valence band of the InₓGa₁₋ₓAs layer 3a. Accordingly, when long-wavelength light at the upper-limit wavelength is received, an electron in the valence band of the GaAs_{1-y}Sb_{y} layer 3b undergoes type-II transition to the conduction band of the InₓGa₁₋ₓAs layer 3a, resulting in generation of a hole in the valence band of the GaAs_{1-y}Sb_{y} layer 3b. The minimum energy difference ΔEmin in this case is illustrated in FIG. 3. The probability of the presence of a hole at the highest level of the valence band of the GaAs_{1-y}Sb_{y} layer 3b is high in the GaAs_{1-y}Sb_{y} layer 3b in view of the potential of the band (having the upside-down potential for a hole). In addition, the probability of the presence of an electron at the lowest level of the conduction band of the InₓGa₁₋ₓAs layer 3a is high in the InₓGa₁₋ₓAs layer 3a in view of the potential. Accordingly, the probability of generation of an electron-hole pair due to receiving of light is high. Stated another way, this type-II configuration has high absorption efficiency.

Even when the bandgap energy of a semiconductor layer constituting an MQW is not uniformly small in the entirety of the layer, as long as the bandgap energy is small in a region near an end surface of the semiconductor layer as illustrated in FIG. 3, an increase in the cutoff wavelength to a longer wavelength is achieved with certainty. Stated another way, extension of the absorption range of a photodiode to a longer wavelength can be achieved.

### 2. Dark Current

In FIG. 3, valence bands and conduction bands corresponding to the average compositions of the semiconductor layers 3a and 3b are represented by broken lines. These broken lines can be regarded as representing valence bands and conduction bands of a band structure having compositions allowing lattice match to InP. According to FIG. 3, at an end surface of each semiconductor layer, the end surface being on the side opposite to the other end surface at which the bandgap energy is minimized, (that is, at the interface L,) the bandgap energy is maximized. As described above, the bandgap energy is minimized at the interface K. The bandgap corresponding to the average composition of a semiconductor layer is the average bandgap energy of the semiconductor layer. The dark current depends on this average bandgap energy. Accordingly, while the dark current is kept at a constant level based on the average composition of a semiconductor layer, the bandgap is minimized at an end surface (interface K at a lower limit of effective bandgap energy) to thereby achieve the extension to a longer wavelength.

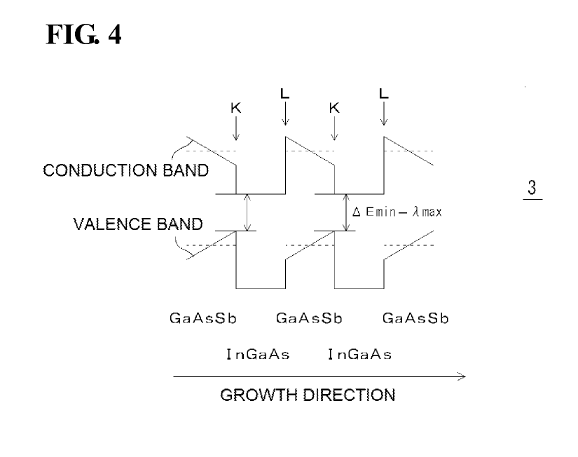

FIG. 4 illustrates a modification with respect to the band structure (FIG. 3) of the absorption layer in the first embodiment of the present invention. A photodiode having the absorption layer 3 of this modification illustrated in FIG. 4 is also a photodiode according to the present invention. In the band structure illustrated in FIG. 3, both of the InₓGa₁₋ₓAs layer 3a and the GaAs_{1-y}Sb_{y} layer 3b have composition gradients in which compositions x and y increase toward the interface K. In contrast, in the modification in FIG. 4, the GaAs_{1-y}Sb_{y} layer 3b alone has a composition gradient in which the composition y increases toward the interface K, whereas the InₓGa₁₋ₓAs layer 3a has no composition gradient. In this case in FIG. 4, although the valence band of the GaAs_{1-y}Sb_{y} layer 3b reaches a high level at the interface K, the conduction band of the InₓGa₁₋ₓAs layer 3a remains flat. Accordingly, the energy difference ΔEmin is not as small as that in the case illustrated in FIG. 3. However, compared with the case where both layers 3a and 3b have no composition gradients, the energy difference of type-II transition can be decreased with certainty to allow contribution to extension of the absorption range to a longer wavelength.

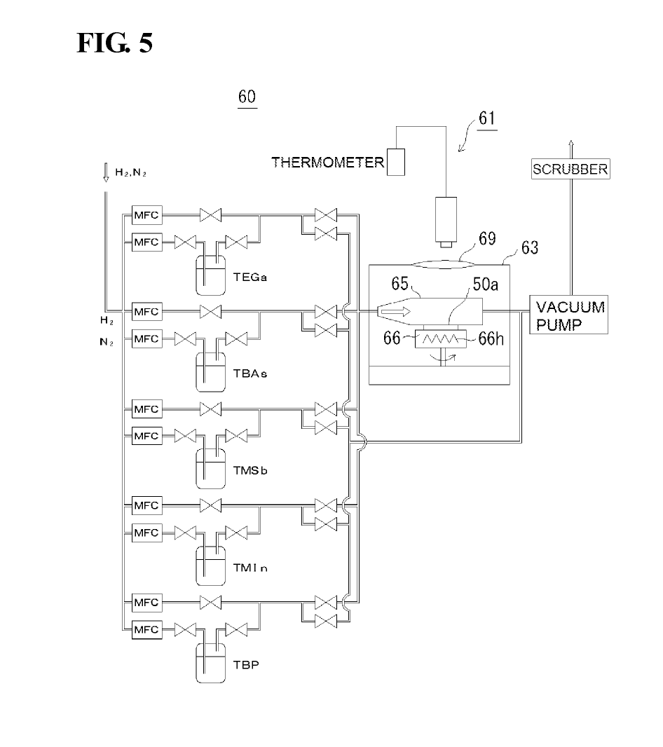

FIG. 5 illustrates the piping system and the like of a deposition apparatus 60 employing metal-organic vapor phase epitaxy using only metal-organic sources. A quartz tube 65 is disposed in a reaction chamber 63. Source gases are introduced into the quartz tube 65. In the quartz tube 65, a substrate table 66 is rotatably and hermetically disposed. The substrate table 66 is equipped with a heater 66h for heating a substrate. The surface temperature of a wafer 50a during deposition is monitored with an infrared thermometer 61 through a window 69 provided in the ceiling portion of the reaction chamber 63. This monitored temperature is referred to as, for example, the growth temperature, the deposition temperature, or the substrate temperature. Regarding formation of an MQW at a temperature of 400° C. or more and 560° C. or less in a production method according to the present invention, this temperature of 400° C. or more and 560° C. or less is measured in the temperature monitoring. Forced evacuation of the quartz tube 65 is performed with a vacuum pump.

Source gases are supplied through pipes connected to the quartz tube 65. The metal-organic vapor phase epitaxy using only metal-organic sources has a feature of supplying all the source gases in the form of metal-organic gases. Accordingly, composition gradients can be formed with high accuracy. Although FIG. 5 does not describe source gases of, for example, impurities, impurities are also introduced in the form of metal-organic gases. The metal-organic source gases are contained in constant temperature baths and kept at constant temperatures. The carrier gases used are hydrogen (H₂) and nitrogen (N₂). The metal-organic gases are carried with the carrier gases and sucked with the vacuum pump to thereby be introduced into the quartz tube 65. The flow rates of the carrier gases are accurately controlled with MFCs (mass-flow controllers). A large number of mass-flow controllers, electromagnetic valves, and the like are automatically controlled with microcomputers. Accordingly, the composition gradients of the InGaAs layer 3a and the GaAsSb layer 3b can be formed with high accuracy.

A method for forming a semiconductor layered structure including the absorption layer 3 on the InP substrate 1 will be described. On an n-type S-doped InP substrate 1, an n-type InP buffer layer 2 is epitaxially grown so as to have a thickness of 150 nm. The n-type doping is preferably performed with tetraethylsilane (TeESi). At this time, source gases used are trimethylindium (TMIn) and tertiarybutylphosphine (TBP). In the growth of the InP buffer layer 2, PH₃ (phosphine), which is an inorganic material, may be used. Even when the InP buffer layer 2 is grown at a growth temperature of about 600° C. or about 600° C. or less, the crystallinity of the underlying InP substrate is not degraded by heating at about 600° C. However, in the formation of the InP window layer 5, which also contains P, an MQW including GaAs_{0.57}Sb_{0.43} is formed thereunder and hence the substrate temperature needs to be strictly kept within the temperature range of, for example, 400° C. or more and 560° C. or less. This is because heating at a temperature more than 560° C. thermally damages GaAsSb, resulting in considerable degradation of the crystallinity; and, when the InP window layer is formed at a temperature less than 400° C., the decomposition efficiency of source gases is considerably decreased and hence the impurity concentration in the InP layer is increased and an InP window layer 5 having high quality is not obtained.

The buffer layer 2 may be constituted by an InP layer alone. However, in a predetermined case, on this InP buffer layer, an n-doped In_{0.53}Ga_{0.47}As layer may be grown so as to have a thickness of 0.15 μm (150 nm). This In_{0.53}Ga_{0.47}As layer is included in the buffer layer 2 in FIG. 1.

Subsequently, the type-II MQW absorption layer 3 in which InGaAs 3a/GaAsSb 3b having composition gradients serve as a pair of the quantum well is formed. In the quantum well, the InGaAs 3a and the GaAsSb 3b each preferably have a film thickness of, for example, 3 nm or more and 10 nm or less. In the photodiode in FIG. 1, the number of the quantum-well pairs is 50 to 300; in view of emphasis on type-II transition, the number of the pairs is preferably about 200 to about 250. The GaAsSb 3b is formed with triethylgallium (TEGa), tertiarybutylarsine (TBAs), and trimethylantimony (TMSb). The gradient of the composition y can be provided by, as the GaAsSb 3b is grown, decreasing the flow rate of TBAs and increasing the flow rate of TMSb so as to compensate for the decrease; since the flow rates can be accurately controlled with time by MFCs, the composition gradient can be easily provided.

The InGaAs 3a may be formed with TEGa, TMIn, and TBAs. The gradient of the In composition x can be provided by complementarily increasing and decreasing the flow rates of TEGa and TMIn with time.

All these source gases are metal-organic gases and the compounds have high molecular weights. Accordingly, the gases are completely decomposed at a relatively low temperature of 400° C. or more and 560° C. or less, contributing to crystal growth. As a result, a temperature difference between the deposition temperature and room temperature can be made small. Thus, strain due to differences in thermal expansion of materials in the photodiode 10 can be reduced and the lattice defect density can be suppressed to a low value. This is advantageous in suppression of dark current.

The Ga (gallium) source may be TEGa (triethylgallium) or trimethylgallium (TMGa). The In (indium) source may be TMIn (trimethylindium) or triethylindium (TEIn). The As (arsenic) source may be TBAs (tertiarybutylarsine) or trimethylarsenic (TMAs). The Sb (antimony) source may be TMSb (trimethylantimony), triethylantimony (TESb), triisopropylantimony (TIPSb), or trisdimethylaminoantimony (TDMASb). By using such sources, a semiconductor element whose MQW has a low impurity concentration and excellent crystallinity can be obtained. As a result, when this element is used for, for example, a photodiode, this photodiode can have a low dark current and high sensitivity.

Hereinafter, the flow of source gases in the formation of the multiple-quantum well structure 3 by metal-organic vapor phase epitaxy using only metal-organic sources will be described. The source gases are carried through pipes, introduced into the quartz tube 65, and discharged. Any number of source gases may be supplied to the quartz tube 65 by increasing the number of pipes. For example, even more than ten source gases can be controlled by opening/closing of electromagnetic valves.

The flow rates of the source gases are controlled with mass-flow controllers (MFCs) illustrated in FIG. 5 and introduction of the source gases into the quartz tube 65 is turned on/off by opening/closing of electromagnetic valves. The quartz tube 65 is forcibly evacuated with the vacuum pump. The source gases do not stagnate in anywhere and the source gases smoothly automatically flow. Accordingly, switching between compositions during the formation of the pair constituting the quantum well is quickly achieved.

A composition gradient can be easily provided by controlling MFCs in accordance with the film thickness during growth. For example, during the growth of the InₓGa₁₋ₓAs 3a, MFCs may be controlled such that, for example, the flow rate of TEIn (triethylindium) is decreased at a constant rate relative to time, the flow rate of TEGa (triethylgallium) is correspondingly increased, and the total of the flow rates is kept constant; or, the flow rate of only one of the sources is increased or decreased. On the other hand, during the growth of the GaAs_{1-y}Sb_{y} 3b, MFCs may be controlled such that, for example, the flow rate of TIPSb (triisopropylantimony) is increased at a constant rate relative to time, the flow rate of TBAs (tertiarybutylarsine) is correspondingly decreased, and the total of the flow rates is kept constant; or, the flow rate of only one of the sources is increased or decreased.

As illustrated in FIG. 5, since the substrate table 66 is rotated, the temperature distribution of source gases does not have orientation relating to source-gas supply side or source-gas discharge side. In addition, since the wafer 50a revolves on the substrate table 66, the source-gas flow in a region near the surface of the wafer 50a is in a turbulent state; and, even source gases in the region near the surface of the wafer 50a, except for source gases in contact with the wafer 50a, have a high velocity component in the flow direction from the supply side to the discharge side. Accordingly, most of heat flowing from the substrate table 66, through the wafer 50a, to the source gases is continuously discharged together with exhaust gas. Thus, a large temperature gradient or temperature gap is generated in the vertical direction from the wafer 50a, through its surface, to the source-gas space.

In an embodiment of the present invention, the substrate is heated to a substrate temperature of 400° C. or more and 560° C. or less, which is a low-temperature range. When metal-organic vapor phase epitaxy using only metal-organic sources is employed at a substrate surface temperature in such a low-temperature range with sources such as TBAs, the sources are efficiently decomposed. Accordingly, source gases flowing in a region very close to the wafer 50a and contributing to growth of a multiple-quantum well structure are limited to those having been efficiently decomposed into forms necessary for the growth.

The surface temperature of the wafer 50a is monitored. From the wafer surface to a position slightly into the source-gas space, as described above, there is a sharp drop in the temperature or a large temperature gap. Accordingly, in the case of a source gas having a decomposition temperature of T1° C., the substrate surface temperature is set to (T1+a) where a is determined in view of, for example, variations in the temperature distribution. In a state where a sharp and large temperature drop or temperature gap is present from the surface of the wafer 50a to the source-gas space, when metal-organic molecules having a large size flow over the wafer surface, compound molecules that decompose to contribute to crystal growth are probably limited to molecules in contact with the surface and molecules located within a layer-thickness range extending for a length of several metal-organic molecules from the surface. Accordingly, metal-organic molecules in contact with the wafer surface and molecules located within a layer-thickness range extending for a length of several metal-organic molecules from the wafer surface probably mainly contribute to crystal growth; and metal-organic molecules located on the outer side are probably discharged, without substantial decomposition, from the quartz tube 65. After metal-organic molecules in a region near the surface of the wafer 50a are decomposed to contribute to crystal growth, metal-organic molecules located on the outer side fill in the region.

Conversely, by setting the wafer surface temperature to be slightly higher than the decomposition temperature of metal-organic molecules, metal-organic molecules that participate in crystal growth can be limited to those located in a thin source-gas layer over the surface of the wafer 50a.

From what is described above, when source gases are selected with electromagnetic valves so as to correspond to the chemical compositions of the pair and introduced under forcible evacuation with a vacuum pump, after growth of a crystal having an old chemical composition due to slight inertia, a crystal having a new chemical composition can be grown without being influenced by the old source gases. As a result, an abrupt composition change can be achieved at the heterointerface. This means that the old source gases do not substantially remain in the quartz tube 65. This is because source gases flowing in a region very close to the wafer 50a and contributing to growth of a multiple-quantum well structure are limited to those having been efficiently decomposed into forms necessary for the growth. Specifically, after one layer of the quantum well is formed, source gases for forming the other layer are introduced by opening/closing of electromagnetic valves under forcible evacuation with a vacuum pump; at this time, there are metal-organic molecules participating in the crystal growth due to slight inertia, but most of additional molecules for the one layer are discharged and no longer present. The closer the wafer surface temperature is to the decomposition temperature of metal-organic molecules, the narrower the range (range from the wafer surface) in which metal-organic molecules located therein participate in crystal growth.

When the multiple-quantum well structure is formed by growth in a temperature range of more than 560° C., phase separation occurs in the GaAsSb layers of the multiple-quantum well structure. Accordingly, the crystal growth surface being clean and having excellent flatness in the multiple-quantum well structure and the multiple-quantum well structure excellent in terms of periodicity and crystallinity cannot be obtained. For this reason, the growth temperature is set in a temperature range of 400° C. or more and 560° C. or less; and, it is important that the deposition is performed by metal-organic vapor phase epitaxy using only metal-organic sources and all the source gases are selected from metal-organic gases having high decomposition efficiency.

### <Method for Producing Photodiode>

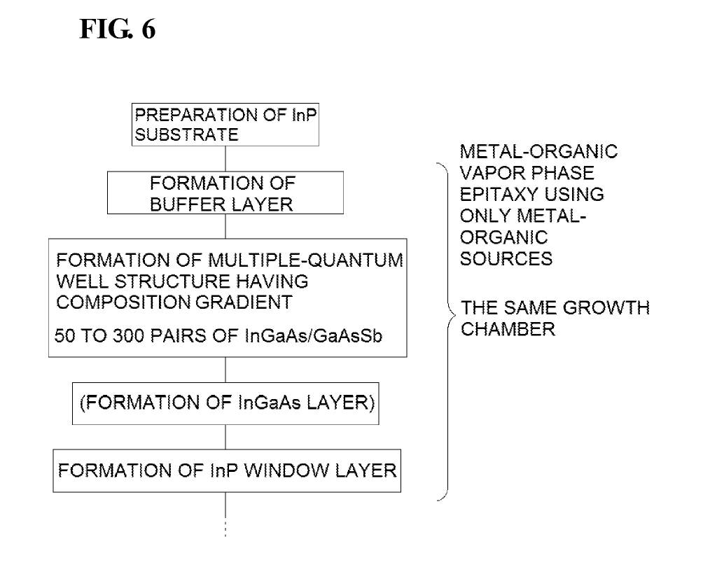

FIG. 6 is a flow chart of a method for producing a photodiode according to the present invention. In the photodiode 10 illustrated in FIG. 1, on the type-II MQW absorption layer 3, the In_{0.53}Ga_{0.47}As diffusive-concentration-distribution-adjusting layer 4 that is lattice-matched to InP is positioned; and, on the In_{0.53}Ga_{0.47}As diffusive-concentration-distribution-adjusting layer 4, the InP window layer 5 is positioned. The p-type region 6 is formed by selective diffusion of Zn, which is a p-type impurity, through the openings of the selective diffusion mask pattern 36 formed on the surface of the InP window layer 5. At the front of the p-type region 6, a p-n junction or a p-i junction is formed. To this p-n junction or p-i junction, a reverse bias voltage is applied to form a depletion layer; charges due to photoelectric conversion are captured so that the brightness of the pixel matches the charge amount. The p-type region 6 or a p-n junction or a p-i junction is a main portion constituting the pixel. The p-electrode 11 in ohmic contact with the p-type region 6 is a pixel electrode. The charges are read out for each pixel between the p-electrode 11 and the n-electrode 12 that is at ground potential. The selective diffusion mask pattern 36 is left without being removed around the p-type region 6 and on the surface of the InP window layer. Furthermore, a passivation layer (not shown) composed of SiON or the like is formed thereon. The selective diffusion mask pattern 36 is left without being removed because, when the p-type region 6 is formed and the selective diffusion mask pattern 36 is then removed to cause exposure to the air, a surface level is formed, in the InP window layer, at the boundary between the surface of the p-type region and the surface of the region having been exposed to the air by removal of the mask pattern, resulting in an increase in the dark current.

It is a point that, from the end of the above-described formation of the MQW to the formation of the InP window layer 5, growth by metal-organic vapor phase epitaxy using only metal-organic sources is continued within the same growth chamber or quartz tube 65. That is, prior to the formation of the InP window layer 5, the wafer 50a is not taken out of the growth chamber and the InP window layer 5 is not formed by another deposition process; accordingly, regrown interfaces are not formed, which is a point. In other words, the InGaAs diffusive-concentration-distribution-adjusting layer 4 and the InP window layer 5 are continuously formed within the quartz tube 65 and hence interfaces 16 and 17 are not regrown interfaces. Accordingly, oxygen and carbon concentrations are each less than the predetermined level. In particular, leakage current does not occur in the cross line between the p-type region 6 and the interface 17. In addition, in the interface 16, the lattice defect density is suppressed to a low value.

In the present embodiment, on the MQW absorption layer 3, for example, the non-doped In_{0.53}Ga_{0.47}As diffusive-concentration-distribution-adjusting layer 4 having a thickness of 1.0 μm is formed. After the formation of the InP window layer 5, when Zn, which is a p-type impurity, is introduced by a selective diffusion method from the InP window layer 5 so as to reach the MQW absorption layer 3, diffusion of Zn at a high concentration into the MQW results in degradation of the crystallinity. The In_{0.53}Ga_{0.47}As diffusive-concentration-distribution-adjusting layer 4 is formed to adjust the diffusion of Zn. The In_{0.53}Ga_{0.47}As diffusive-concentration-distribution-adjusting layer 4 may be formed as described above, or may be omitted.

As a result of the selective diffusion, the p-type region 6 is formed and a p-n junction or a p-i junction is formed at the front of the p-type region 6. Even when the In_{0.53}Ga_{0.47}As diffusive-concentration-distribution-adjusting layer 4 is inserted and it is a non-doped layer, In_{0.53}Ga_{0.47}As has a small bandgap energy and hence the photodiode can be made to have a low electric resistance. By decreasing the electric resistance, the responsivity can be enhanced and moving images having high image quality can be obtained.

While the wafer 50a is continuously left in the same quartz tube 65, on the In_{0.53}Ga_{0.47}As diffusive-concentration-distribution-adjusting layer 4, the undoped InP window layer 5 is preferably epitaxially grown by metal-organic vapor phase epitaxy using only metal-organic sources so as to have a thickness of, for example, 0.8 μm. As described above, the source gases are trimethylindium (TMIn) and tertiarybutylphosphine (TBP). By using these source gases, the growth temperature for the InP window layer 5 can be made to be 400° C. or more and 560° C. or less, further 535° C. or less. As a result, GaAsSb of the MQW underlying the InP window layer 5 is not thermally damaged and the crystallinity of the MQW is not degraded. In the formation of the InP window layer 5, since the MQW containing GaAsSb is formed thereunder, the substrate temperature needs to be strictly maintained in the range of, for example, 400° C. or more and 560° C. or less. This is because heating to more than 560° C. thermally damages GaAsSb and the crystallinity is considerably degraded; and, when an InP window layer is formed at a temperature less than 400° C., the decomposition efficiency of source gases becomes very low and hence the impurity concentration in the InP window layer 5 becomes high and the InP window layer 5 having high quality is not obtained.

As described above, an MQW has been required to be formed by molecular beam epitaxy (MBE). However, growth of an InP window layer by MBE requires use of solid phosphorus source and hence has problems in terms of safety and the like; in addition, the production efficiency needs to be enhanced.

Before the present invention has been accomplished, the interface between the In_{0.53}Ga_{0.47}As diffusive-concentration-distribution-adjusting layer and the InP window layer was a regrown interface having been exposed to the air. Such a regrown interface can be identified through secondary ion mass spectrometry in which it satisfies at least one of an oxygen concentration of 1×10¹⁷ cm⁻³ or more and a carbon concentration of 1×10¹⁷ cm⁻³ or more. The regrown interface forms a cross line through the p-type region; leakage current occurs in the cross line and image quality is considerably degraded. Alternatively, for example, in the case of growth of an InP window layer by MOVPE (metal-organic vapor phase epitaxy not using only metal-organic sources) simply employing phosphine (PH₃) as the phosphorus source, the decomposition temperature of phosphine is high and the underlying GaAsSb is thermally damaged, resulting in degradation of the crystallinity of the MQW.

### EXAMPLES

By performing computer simulations of band structures, the degrees of achieving extension to a longer wavelength by composition gradients illustrated in FIGS. 2 to 4 were examined. The following three cases were examined as described in Table I below.

### (Case 1: Top Row in Table I):

The GaAs_{1-y}Sb_{y} layer 3b has a composition gradient, whereas the InₓGa₁₋ₓAs layer 3a has a flat composition and is lattice-matched to InP. This case corresponds to the configuration in FIG. 4, which is described as an embodiment of the present invention. In_{0.53}Ga_{0.47}As has the composition that corresponds to a lattice mismatch of 0.

### (Case 2: Middle Row in Table I):

Both of the GaAs_{1-y}Sb_{y} layer 3b and the InₓGa₁₋ₓAs layer 3a have composition gradients. The range of x in the InₓGa₁₋ₓAs layer 3a is 0.48 (Top) to 0.58 (Bottom), which is a relatively narrow range. In this case, InGaAs has a lattice mismatch of ±0.40%.

### (Case 3: Bottom Row in Table I):

Both of the GaAs_{1-y}Sb_{y} layer 3b and the InₓGa₁₋ₓAs layer 3a have composition gradients. The range of x in the InₓGa₁₋ₓAs layer 3a is 0.43 (Top) to 0.63 (Bottom), which is a wide range. In this case, InGaAs has a lattice mismatch of ±0.66%.

Regarding these three cases, the degree of an increase in the long-wavelength upper limit (cutoff wavelength=λmax) of the absorption range was determined.

The results are described in Table I.

TABLE I

| | | | | | Degree of |
|---|---|---|---|---|---|
| | | | | | increase in |
| | | In composition x | | | cutoff |
| Sb composition y | | of InₓGa₁₋ₓAs | | | wavelength |
| of GaAs_{1-y}Sb_{y} | | | | Mismatch | to longer |
| Bottom | Top | Bottom | Top | of | wavelength *⁾ |
| (L) | (K) | (K) | (L) | InGaAs | (nm) |
| 0.43 | 0.54 | 0.53 | 0.53 | ±0% | 100 |
| 0.43 | 0.54 | 0.58 | 0.48 | ±0.40% | 160 |
| 0.43 | 0.54 | 0.63 | 0.43 | ±0.66% | 200 |

*⁾ The degree of an increase in the long-wavelength limit with respect to a cutoff wavelength that is provided in the case where GaAs_{1-y}Sb_{y} and InₓGa₁₋ₓAs both have no composition gradient and are lattice matched

As described in Table I, in Case 1 having a band structure corresponding to the above-described embodiment in FIG. 4, extension of the absorption range to a longer wavelength by about 100 nm is achieved. In Case 3, extension of the absorption range to a longer wavelength by about 200 nm is achieved. For example, when Case 3 according to the present invention is applied to a type-II MQW InGaAs/GaAsSb lattice-matched to InP and having an absorption wavelength range of up to 2 μm, the upper-limit wavelength can be increased to 2.2 μm. Such an increase in the upper-limit wavelength can considerably enhance the usefulness depending on the wavelengths of absorption bands of target objects.

Embodiments of the present invention have been described so far. However, embodiments of the present invention disclosed above are given by way of illustration, and the scope of the present invention is not limited to these embodiments. The scope of the present invention is indicated by Claims and embraces all the modifications within the meaning and range of equivalency of the Claims.

### INDUSTRIAL APPLICABILITY

In a photodiode according to the present invention, extension of the sensitivity range to a longer wavelength in the near-infrared region can be achieved without increasing the dark current, which can considerably enhance the usefulness depending on target objects.

1. A photodiode containing a III-V compound semiconductor, the photodiode comprising:
an absorption layer that is positioned on a III-V compound semiconductor substrate and has a type-II multiple-quantum well structure in which a first semiconductor layer and a second semiconductor layer are alternately layered,
wherein the first semiconductor layer has a composition gradient in a thickness direction in which a bandgap energy of the first semiconductor layer decreases toward a top surface or a bottom surface of the first semiconductor layer.

2. The photodiode according to claim 1, wherein the second semiconductor layer has a composition gradient in a thickness direction in which a bandgap energy of the second semiconductor layer decreases toward a surface of the second semiconductor layer, the surface being in contact with an end surface of the first semiconductor layer having the gradient in which the bandgap energy of the first semiconductor layer decreases toward the end surface.

3. The photodiode according to claim 1, wherein, in at least one semiconductor layer that is selected from the first semiconductor layer and the second semiconductor layer and has the composition gradient,
a composition at an end surface at which the bandgap energy is minimized corresponds to a lattice mismatch of more than 0.2% in terms of variation in lattice constant with respect to an average composition of the semiconductor layer.

4. The photodiode according to claim 1, wherein, in at least one semiconductor layer selected from the first semiconductor layer and the second semiconductor layer, an average composition corresponds to a lattice mismatch within ±1% in terms of variation in lattice constant with respect to the III-V compound semiconductor substrate.

5. The photodiode according to claim 1, wherein one of the first and second semiconductor layers that has a higher valence band in terms of potential energy than another one of the first and second semiconductor layers contains at least one of Ga, As, and Sb.

6. The photodiode according to claim 1, wherein one of the first and second semiconductor layers that has a lower valence band in terms of potential energy than another one of the first and second semiconductor layers contains at least one of In, Ga, and As.

7. The photodiode according to claim 1, wherein the multiple-quantum well structure is formed of InₓGa₁₋ₓAs and GaAs_{1-y}Sb_{y}, the InₓGa₁₋ₓAs layer has an average composition xₐᵥₑ (0.38≦xₐᵥₑ≦0.68), and the GaAs_{1-y}Sb_{y} layer has an average composition yₐᵥₑ (0.36≦yₐᵥₑ≦0.62).

8. The photodiode according to claim 1, wherein the III-V compound semiconductor substrate is an InP substrate.

9. A method for producing a photodiode containing a III-V compound semiconductor, the method comprising:
a step of forming an absorption layer having a type-II multiple-quantum well structure by alternately layering a first semiconductor layer and a second semiconductor layer on an InP substrate,
wherein, in the step of forming the multiple-quantum well structure, the first semiconductor layer is formed so as to have a composition gradient in a thickness direction in which a bandgap energy of the first semiconductor layer decreases toward a top surface or a bottom surface of the first semiconductor layer.

10. The method for producing a photodiode according to claim 9, wherein, in the step of forming the multiple-quantum well structure, the second semiconductor layer is formed so as to have a composition gradient in a thickness direction in which a bandgap energy of the second semiconductor layer decreases toward a surface of the second semiconductor layer, the surface being in contact with an end surface of the first semiconductor layer having the gradient in which the bandgap energy of the first semiconductor layer decreases toward the end surface.

11. The method for producing a photodiode according to claim 9, wherein, when the multiple-quantum well structure is formed by metal-organic vapor phase epitaxy using only metal-organic sources such that the first semiconductor layer or each of the first semiconductor layer and the second semiconductor layer is formed so as to have the composition gradient, the composition gradient is provided by adjusting a mass-flow controller incorporated in a growth system for the metal-organic vapor phase epitaxy using only metal-organic sources.
